(19) United States
(12) Patent Application Publication
(10) Pub. No.: US 2002/0180006 A1
(43) Pub. Date: Dec. 5, 2002

(54) Ferroelectric-superconductor heterostructures in solid state quantum computing systems

(76) Inventors: Marcel Franz, Vancouver (CA); Geordie Rose, Vancouver (CA); Jeremy Hilton, Vancouver (CA)

Correspondence Address: SKJERVEN MORRILL LLP, 25 METRO DRIVE, SUITE 700, SAN JOSE, CA, 95110, US

(21) Appl. No.: 09/873,013

(22) Filed: May 31, 2001

(51) Int. Cl. H01L 29/76; H01L 29/94; H01L 31/062; H01L 39/00

(52) U.S. Cl. 257/661; 257/295

(57) ABSTRACT

A ferroelectric is used to switch a superconductor computer element. Part of the superconductor element can be a high temperature superconductor layer, doped to the vicinity of a superconductor insulator transition. The ferroelectric overlies the superconductor layer, forming a heterostructure. A voltage can be applied to polarize the ferroelectric. This polarization in turn generates an electric field for the superconductor layer, effectively changing its doping. For sufficiently large voltages the superconductor transitions into an insulating state. When included into a sensor, this heterostructure can function as a switch, used in relation to reading the state of qubits. When coupling two qubits, this heterostructure can be used to control the entanglement of the two qubits.

### BACKGROUND

1. Field of the Invention

This invention relates to ferroelectric-superconductor heterostructures, and to high temperature solid state quantum computing devices.

2. Description of Related Art

A quantum bit (qubit) is an elementary component of a quantum computer or a quantum information device. The qubit is a bistable device capable of supporting the coherent evolution of its quantum states in a controlled fashion. Prime candidates for systems with two quantum states are superconducting devices, such as ring shaped Superconducting Quantum Interference Devices (“SQUIDs”).

Matter in the superconducting state is capable of supporting currents with zero resistance, so-called supercurrents. This zero resistance flow is possible because electrons join in Cooper pairs, forming a superconducting condensate. Supercurrent carrying states consist of a macroscopic number of electrons, all in the same quantum state, and correspondingly the value of the current, a physical observable, has a very narrow distribution with a width inversely proportional to the number of the constituent electrons. The properties of such quantum states are easy to observe with very little uncertainty. Furthermore, tunneling between states with different supercurrents is possible, allowing for transitions between these quantum states. For these reasons, for example, left and right moving supercurrent carrying states in a SQUID are prime candidates for the quantum states of a qubit in a quantum computer.

Proposals have been made and efforts are underway to fabricate qubits by patterning films of copper oxide superconductors as described, for example, by A. M. Zagoskin, “A scalable, tunable qubit, based on a clean DND or grain boundary D-D junction,” LANL, cond-mat/9903170 (March 1999, and the references therein, incorporated hereby in its entirety. During the fabrication it is necessary to mechanically, chemically or otherwise etch islands of these materials of various shapes and crystallographic orientations and connect them via weak links. Because of the nature of these materials and the need to fabricate islands of mesoscopic sizes, the techniques involved are complicated and costly. Furthermore, once the pattern is formed, it is generally difficult to change it. On the other hand, successful integration of the individual qubits into a practical quantum computer or other device requires these patterns to be flexible, in that one should be able to open and close connections between individual qubits reversibly. In particular it is essential for the operation of any quantum computing device that qubits are typically isolated from each other, but connected in a specific way when the qubits execute a computational step, for example, by entangling their quantum states. Finally, any increase in the operating temperature of these devices will make their applications easier. Thus, there is a need for reversible switching mechanisms for solid state quantum computing systems, capable of operating at high temperatures.

An important characteristic of quantum computing systems is the tunneling rate of the qubit. The tunneling rate of the qubit, or the rate of quantum evolution is the frequency by which the state of the qubit tunnels from one of its quantum states to the other. The tunneling rate dictates the speed of operation of all the other components in the quantum computing system. For example, in order to read the state of a qubit, the qubit can be grounded, which collapses the wavefunction of the qubit into one of its quantum states. If the qubit could not be grounded at a frequency higher than its tunneling rate, then the qubit would change its state during the grounding procedure. Typically, the tunneling rate of a qubit is of the order of 10 GHz. The requirement to exceed this value places a stringent bound on the switching rate of any device that interfaces with the qubit, and the other parts of the quantum computing system.

A single electron transistor (SET) is a switch that includes a superconducting mesoscopic island isolated by two Josephson tunnel junctions. Typically, the SET is controlled by a gate voltage, where the coupling between the gate and the SET is capacitive. By modulating the gate voltage the SET can be opened and closed, acting as a switch. The SET can perform switching functions for the transport of single electrons or Cooper pairs. The operation and behavior of SETs is known in the art, and is described in detail, for example, by P Joyez et al. In “Observation of Parity-Induced Supression of Josephson Tunneling in the Superconducting Single Electron Transistor,” Physical Review Letters, Vol. 72, No. 15, 11 April 1994, and the references therein.

Coherence is present in a superconducting switch, if a supercurrent can pass through it. Coherent switches are important elements of the solid state quantum computing systems, particularly in supporting the entanglement of the quantum states of the qubits with minimal losses. Low temperature SETs, made of materials such as niobium or aluminum, have been shown to achieve coherence, see for example M. T. Tuominen, J. M. Hergenrother, T. S. Tighe, and M. Tinkham, “Experimental Evidence for Parity-Based 2e Periodicity in an Superconducting Single-Electron Transistor,” Phys. Rev. Lett. 69, 1997 (Sep. 28, 1992). However, current SETs made out of high temperature superconducting materials have not been shown to achieve coherence. This is in part due to the complications of working at higher temperatures.

High-temperature copper-oxide superconductors (“cuprates”) are layered perovskite materials in which superconductivity depends strongly on the doping concentration. For example, in the compound GdBa₂Cu₃O₇₋ₓ the doping of the system is achieved by changing the oxygen concentration x. As can be seen in the typical phase diagram of cuprates in FIG. 1, varying the doping x in the vicinity of the superconductor-insulator transition point, x_{c}, at low temperatures, one can induce a transition from the superconducting phase to the insulating phase and vice versa.

The doping of a bulk material is typically determined by its chemical composition, such as the oxygen concentration x. However, as recently demonstrated by C. H. Ahn, S. Garigli, P. Paruch, T. Tybell, L. Antognazza, J.-M. Triscone, “Electrostatic Modulation of Superconductivity in Ultrathin GdBa2Cu3O7-x Films,” Science 284, 1152 (May 14, 1999), in very thin films, with thickness not exceeding the Thomas-Fermi screeening length, doping can be substantially modified by applying an electric field. Such an electric field can be provided by, for example, a nearby ferroelectric material.

The utility of the ferroelectric field effect for forming devices with high-T_{c}, superconductors has been described before in U.S. Pat. No. 5,274,249. The operating temperature of the device is chosen to be around the critical temperature of the superconducting material. The device consists of a thin superconducting film, two superconducting electrodes, of greater thickness than the film, a ferroelectric layer over the thin film superconductor, and a gate electrode over the ferroelectric. If the ferroelectric is not polarized, the thin film is superconducting, and thus it is capable of supporting a supercurrent, in effect closing the switch. Whereas if there is a sufficient voltage applied at the gate, the ferroelectric becomes polarized and generates an electric field. This electric field in turn reduces the carrier density of the thin film superconductor such that it becomes an insulator. This prevents the flow of the supercurrents, in effect opening the switch.

The use of the ferroelectric effect in quantum information processing has been proposed by Jeremy Levy. See, for example, J. Levy, “Quantum Information Processing with Ferroelectrically Coupled Quantum Dots”, LANL preprint, quant-ph/0101026 (2001), and the references therein, wherein a quantum information processor is proposed using ferroelectrically coupled quantum dots. The semi-conducting dots are coupled directly by a ferroelectric material, which is manipulated by laser energy. The proposal does not involve the use of superconductors, and applying voltage to the ferroelectric. The feasibility of the proposal is questionable as the proposed proximity of the ferroelectric material to the quantum dots can destroy the coherence required for the quantum bit operations. The proposed method addresses a different approach to the development of quantum computers which has limited scalability, and, therefore, practicality of the method is drastically limiting as well.

Fabrication of the ferroelectric-superconductor heterostructures is known in the art. It is described, for example, in R. Ramesh, A. Inam, W. K. Chan, F. Tillerot, B. Wilkens, C. C. Chang, T. Sands, J. M. Tarascon, V. G. Keramidas, “Ferroelectric PbZr_{0.2}Ti_{0.8}O₃ thin films on epitaxial Y—Ba—Cu—O,” Appl. Phys. Lett. 59, 3542 (Dec. 30, 1991), and in R. Ramesh, A. Inam, B. Wilkens, W. K. Chan, T. Sands, J. M. Tarascon D. K. Fork, T. H. Geballe, J. Evans, J. Bullington. “Ferroelectric bismuth titanate/superconductor (Y—Ba—Cu—O) thin-film heterostructures on silicon.” Appl. Phys. Lett. 59, 1782 (Sep. 20, 1991). These devices include a substrate, a thin film of a high temperature superconductor, a thin film of a ferroelectric material, and electrodes.

The ferroelectric field effect is strong, if the superconducting film is ultra-thin, typically a couple mono-layers. It is typically formed on a substrate, such as SrTiO₃, with a buffer layer of PrBa₂Cu₃O (PBCO) deposited on top of it. The thickness of the buffer is typically 6 monolayers, or about 7.2 nm. Next, the superconductor is deposited on the buffer with a thickness of a couple of monolayers, or approximately 2.4 nm. Methods for fabricating ultra-thin films of YBCO are known in the art, as described in, for example, T. Terashima, K. Shimura, Y. Bando, Y. Matsuda, A. Fujiyama, and S. Komiyama, “Superconductivity of One-Unit-Cell Thick YBa₂Cu₃O₇ Thin Film,” Phys. Rev. Lett. 67, 1362 (Sep. 2, 1991).

In summary, coherent switching between the quantum states of qubits, such as different supercurrent carrying states of SQUIDs, has not been achieved yet in high temperature superconductors. Thus, a mechanism for coherent switching between supercurrent carrying states in solid state quantum computing systems is needed. The coherent switch should operate reversibly, at a high frequency, and should have a reasonably simple structure for integration.

### SUMMARY OF THE INVENTION

In accordance with the present invention a ferroelectric-superconductor heterostructure is presented, which is operable in quantum computing systems. The heterostructure can be utilized for switching and other purposes.

In accordance with an embodiment of the invention, a high speed, coherent, nonvolatile switch in a solid state quantum computing system includes a substrate layer, a superconductor layer, such as, for example, high temperature superconductor, overlying the substrate layer, a ferroelectric layer, such as Pb(ZrₓTi₂−x)O₃ overlying the superconductor, and a metallic layer over the ferroelectric layer, acting as an electrode.

The superconductor can have a thickness of several monolayers of the superconducting material. A buffer layer can be deposited between the superconducting material and the ferroelectric material. When no voltage is applied to the electrode, the ferroelectric is unpolarized, therefore the superconductor beneath the ferroelectric material is in its superconducting state. Thus, the switch is closed. When a voltage is applied to the electrode, the ferroelectric polarizes, generating an electric field. This electric field changes the chemical potential of the dopants in the superconductor, in effect pulling charge carriers out of the superconductor, leaving the region underlying the ferroelectric insulating. The change of state of the superconductor can occur faster than the tunneling rate between the quantum states, thus satisfying the speed requirement for the appropriate operations of a qubit.

In accordance with another embodiment of the invention, a tuneable Josephson junction includes a layer of ferroelectric, such as Pb(ZrₓTi₂−x)O₃, overlying a superconductor, a plurality of electrodes deposited across the width of said ferroelectric. In operation, when a voltage is applied to one of the electrodes, the corresponding part of the ferroelectric polarizes, in effect pulling the charges off the superconductor beneath it, making the underlying superconductor material insulating. Thus, by applying different voltages to the electrodes separately, sections of the underlying superconductor can be made insulating, leaving the other sections superconducting.

As outlined above, coherent switches are employed in solid state quantum computing systems. The process of quantum computing includes entanglement of the quantum states of qubits during the execution of quantum algorithms. In order to accomplish the entanglement, the qubits can be directly connected by superconducting links without disturbing the sensitive wavefunctions of the qubits. It is necessary only for portions of the overall algorithm to have the quantum states of the qubits directly entangled. For the remaining time the qubits can be disconnected. A coherent switch can be employed to control the connection between the qubits.

In another embodiment of the invention an outer dc-SQUID surrounds an inner superconducting loop that includes at least one Josephson junction. Since the supercurrents of the quantum states of the inner loop are directly related to the supercurrents of the outer dc-SQUID, the outer dc-SQUID can be used to read the quantum states of the inner loop, which is serving as a qubit. However, in order to perform quantum computations, the inner loop should be decoupled from the outer dc-SQUID. This has been accomplished previously by breaking the outer dc-SQUID so that supercurrents could not flow in it. An application of the present invention would provide a mechanism for decoupling the inner loop by including a coherent switch into the outer dc-SQUID. When the switch is closed, supercurrents can flow in the outer dc-SQUID, and thus the superconducting loops are coupled. When the switch is open, no supercurrent flows in the outer dc-SQUID, thus the SQUIDs are decoupled. This architecture therefore provides a reversible mechanism for reading the quantum state of the inner loop.

### DESCRIPTION OF THE FIGURES

FIG. 1 illustrates a phase diagram on the doping—temperature plane of cuprate superconductors.

FIGS. 2a through 2e illustrate the fabrication of embodiments of the invention.

FIGS. 3a and 3b illustrate the operation of an embodiment of the invention.

FIG. 4 illustrates an embodiment of the invention.

FIGS. 5a through 5d illustrate the fabrication of an embodiment of the invention.

FIGS. 6a through 6d illustrate the fabrication of an embodiment of the invention.

FIG. 7a illustrates a superconducting loop inside a dc-SQUID.

FIG. 7b illustrates an embodiment of the invention, wherein the dc-SQUID can be decoupled from the inner superconducting loop.

FIG. 8 illustrates an embodiment of the invention, involving superconductors with pairing symmetry corresponding to non-zero angular momentum.

FIG. 9 illustrates an embodiment of the invention involving multiple qubits.

### DETAILED DESCRIPTION

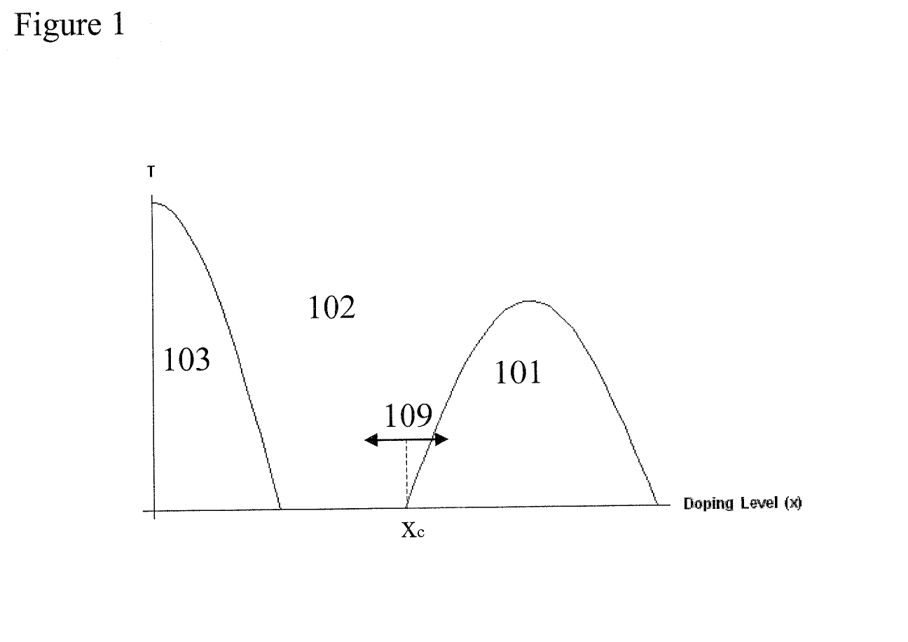

FIG. 1 illustrates a phase diagram for high temperature superconductors in the doping concentration—temperature, or (x,T), plane. At zero temperature for x greater than x_{c} the system is in its superconducting phase. At finite temperature the superconducting region shrinks, as illustrated by region 101. Region 102 represents a region where the material is an insulator at low temperatures and a “strange metal” at higher temperatures. The material is an anti-ferromagnet in region 103. A superconductor-insulator transition takes place at zero temperature at the critical doping level x_{c}. The ferroelectric field changes the effective doping of the material. As shown by the arrows 109, the ferroelectric effect can increase or decrease the effective doping. Therefore when the nominal doping is near x_{c}, the ferroelectric field can induce a phase transition between the superconducting state and the insulating state.

In operation, the polarized ferroelectric exerts an electric field on the superconductor, modifying its local chemical potential. Change in the local chemical potential in turn increases or decreases x depending on the polarity of the electric field of the ferroelectric: up (↑), which represents a positive charge at the top of the material and a negative charge at the bottom, or down (↓), which is charged oppositely to that of the up polarization. Thus, if the chemical composition of the superconductor is tuned so that its nominal doping is very close to x_{c} in the absence of an external electric field, the ferroelectric field can modify x such that x↑>x_{c} and x↓<x_{c}. Here, x↑ and x↓ denote the effective doping of the superconductor for the up (↑) and down (↓) polarization states of the ferroelectric, respectively.

Coherent switches can be fabricated using the just described ferroelectric effect. In an embodiment of the invention a superconductor overlies a substrate, a ferroelectric material overlies the superconductor, and a electrode overlies the ferroelectric. The superconducting material can be, for example, a high temperature superconductor, or a superconductor with a pairing symmetry corresponding to a non-zero angular momentum. In some embodiments a buffer overlies the substrate. The buffer can have a lattice structure that matches closely that of the superconducting material. In another embodiment, a buffer can be deposited on the superconductor. The buffer can donate hole carriers to the underlying superconducting material, thus increasing the effective doping level of the superconductor without changing the actual chemical structure of the superconductor. This has been shown to induce superconductivity in ultra-thin films that otherwise would not be superconducting, as described, for example, by T. Terashima, K. Shimura, and Y. Bando, “Superconductivity of One-Unit-Cell Thick YBa₂Cu₃O₇ Thin Film,” Phys. Rev. Lett. 67, 1362 (Sep. 2, 1991).

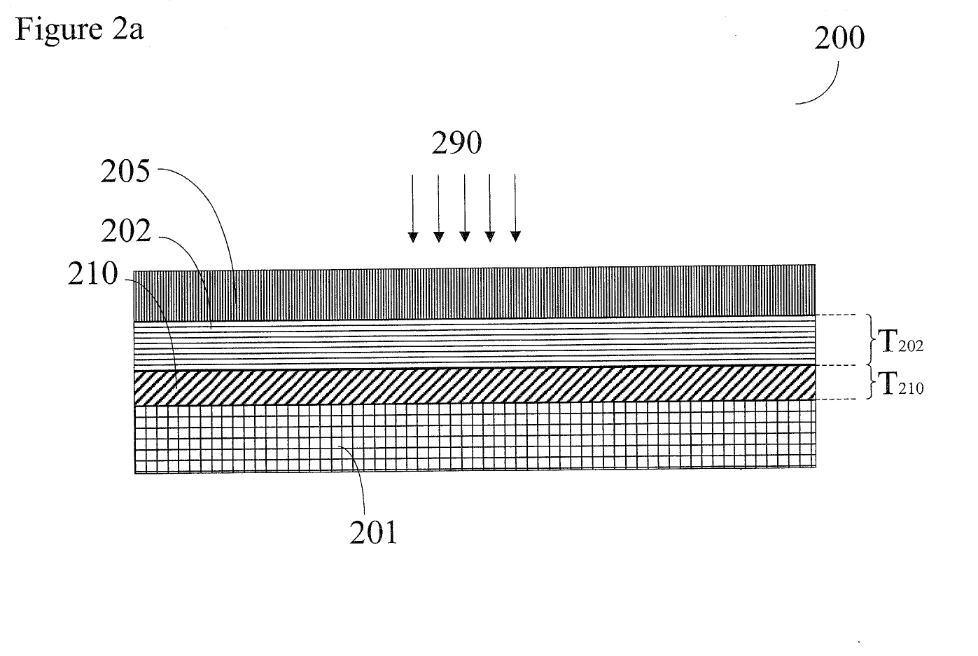

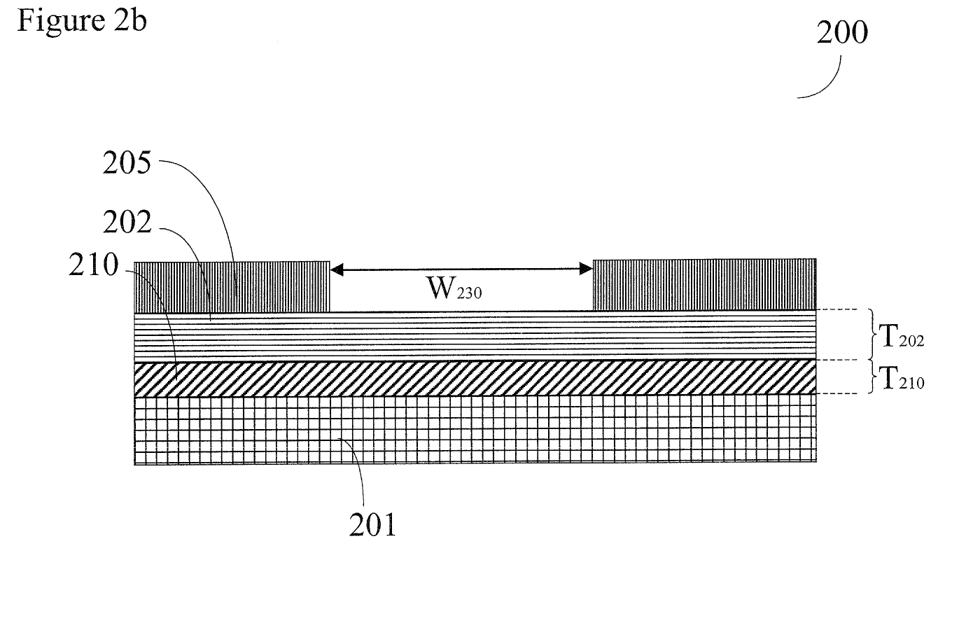

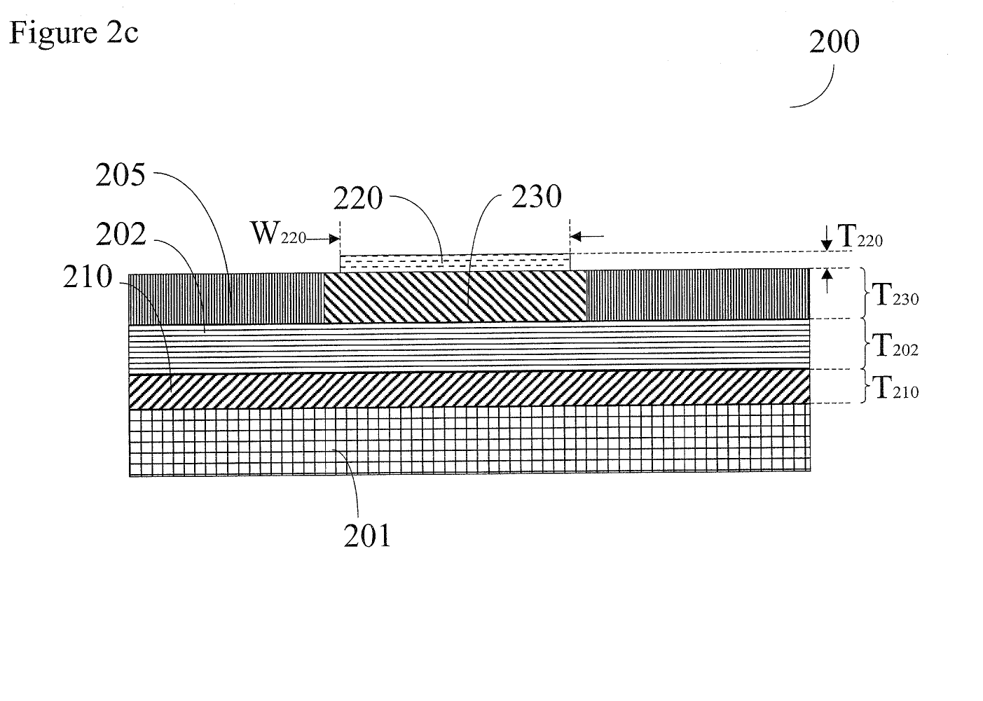

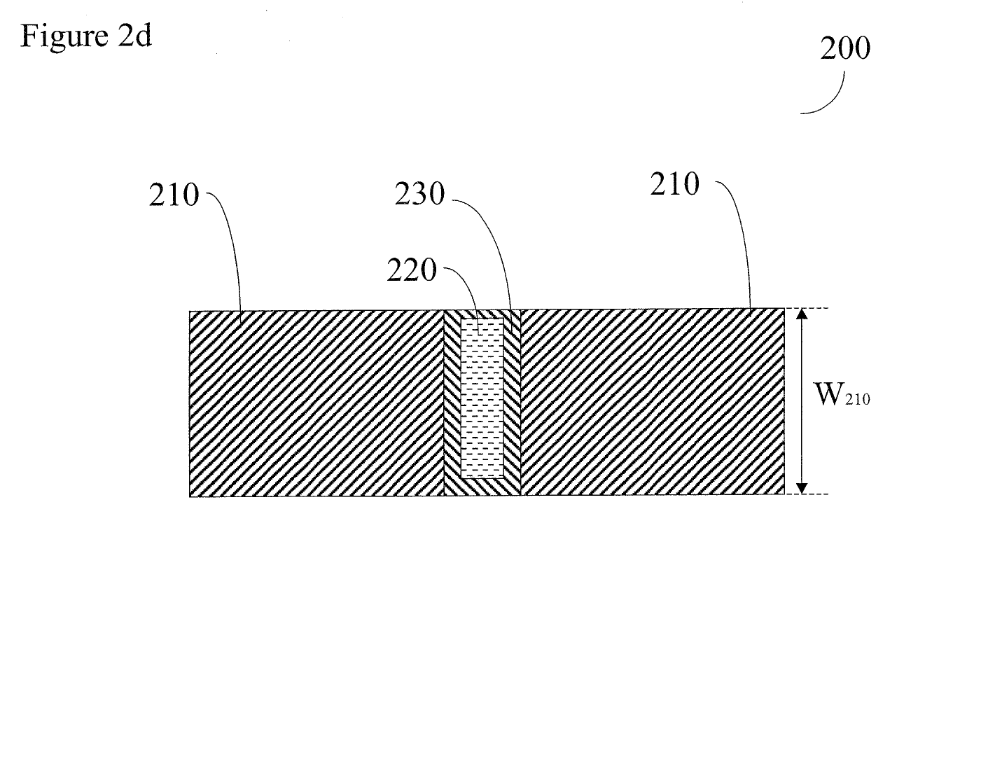

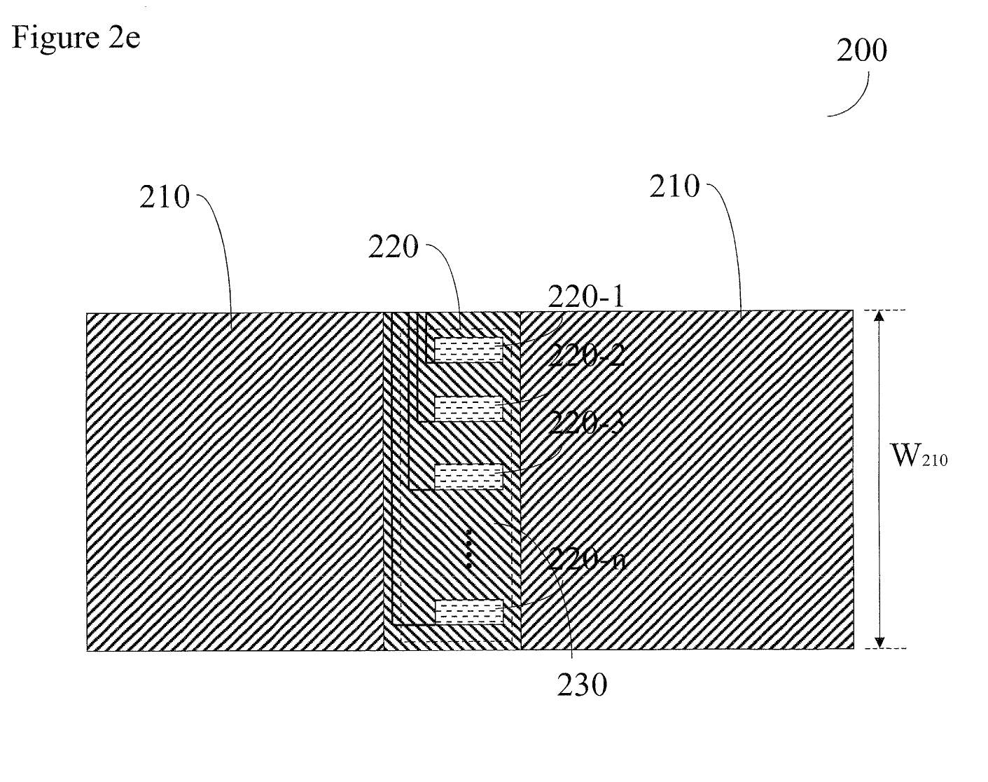

FIGS. 2a through 2e illustrate some further embodiment of the invention. FIG. 2a illustrates a cross-sectional view of the materials that can be used to provide coherent switch 200. A superconductor 210 of thickness T₂₁₀ can overlie a substrate 201, a buffer 202 of thickness T₂₀₂ can overlie superconductor 210, and a mask 205 can overlie buffer 202. Using well-known lithographic techniques a masked region 290 can be removed from superconductor 210. FIG. 2b illustrates masked region 290 removed with width W₂₃₀. Next a ferroelectric 230 can be deposited with a thickness T₂₃₀, using, for example, off axis radio-frequency magnetron sputtering. Finally, an electrode 220 can be deposited on ferroelectric 230 with width W₂₂₀ and thickness T₂₂₀.

In some further embodiment, the thickness T₂₁₀ of superconductor 210 can be about 1 nm to about 20 nm, preferably about 2.4 nm, the thickness T₂₀₂ of buffer layer can be about 2 nm to about 100 nm, preferably about 7.2 nm, the thickness of the ferroelectric layer T₂₃₀ can be about 50 nm to about 10,000 nm, preferably about 300 nm. In another embodiment, no buffer layer is used and ferroelectric 230 can be deposited epitaxially on superconductor 210.

FIG. 2d illustrates a top view of some further embodiment. Electrode 220 can extend across the width of ferroelectric 230. Ferroelectric 230 can extend across the width of superconductor 210. In operation, application of a voltage to electrode 220 can polarize ferroelectric 230. The polarized ferroelectric 230 can pull dopant charge carriers out of underlying superconductor 210, modifying the effective doping of superconductor 210. When the voltage is removed, ferroelectric 230 loses its polarization, and the charge carriers can return to superconductor 210.

FIG. 2e illustrates a top view of some further embodiment. Electrode 220 may include a group of electrodes 220-1 through 220-n, positioned across the width of ferroelectric 230. In operation, electrodes 220-1 through 220-n provide local electric fields that effect localized regions of underlying superconductor 210. This embodiment is capable of turning localized regions of superconductor 210 individually insulating, as well as coherently switching the entire superconductor 210 insulating.

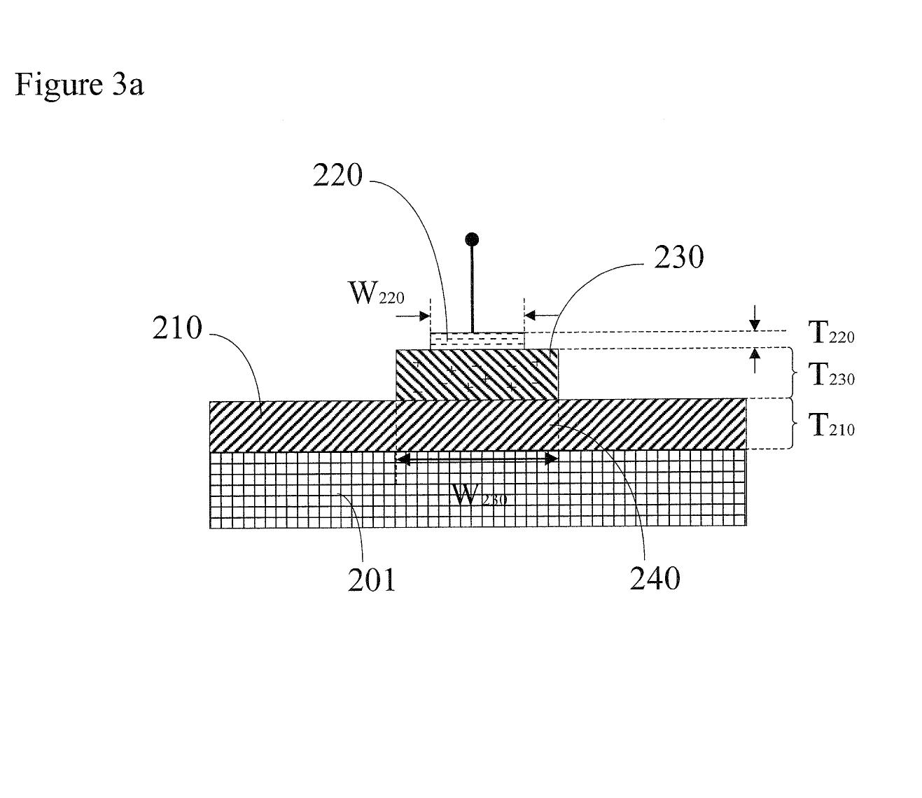

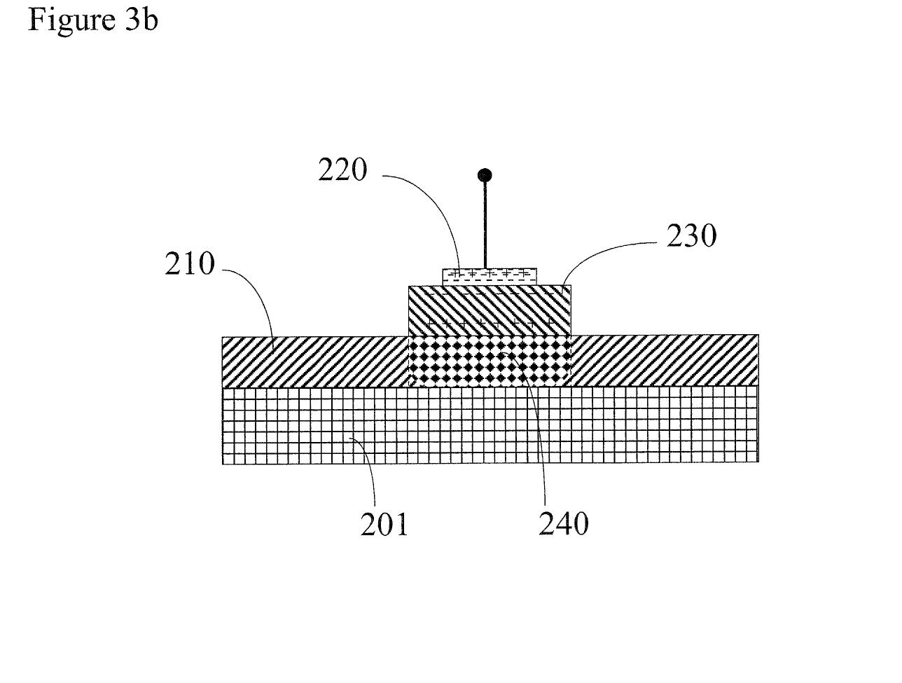

FIG. 3a illustrates a possible mode of operation of the invention. In FIG. 3a no voltage is applied to electrode 220, thus ferroelectric 230 is relaxed. The relaxed state of ferroelectric 230 is illustrated by a random arrangement of its internal charges. Underlying superconducting region 240 underneath ferroelectric 230 is unaffected by the relaxed state of ferroelectric 230. FIG. 3b illustrates that applying a sufficient voltage to electrode 220 can polarize ferroelectric 230 by aligning the charges within. Polarized ferroelectric 230 generates an electric field, which affects underlying superconducting region 240. The electric field can remove charge carriers from underlying superconducting region 240, changing its effective doping. If this change of effective doping sweeps through the critical doping x_{c}, underlying superconducting region 240 changes from superconducting to insulating.

In other embodiments of the invention additional layers can be included as well. These layers may include buffer layers, whose lattice structure closely matches that of the superconducting material, and additional superconducting layers.

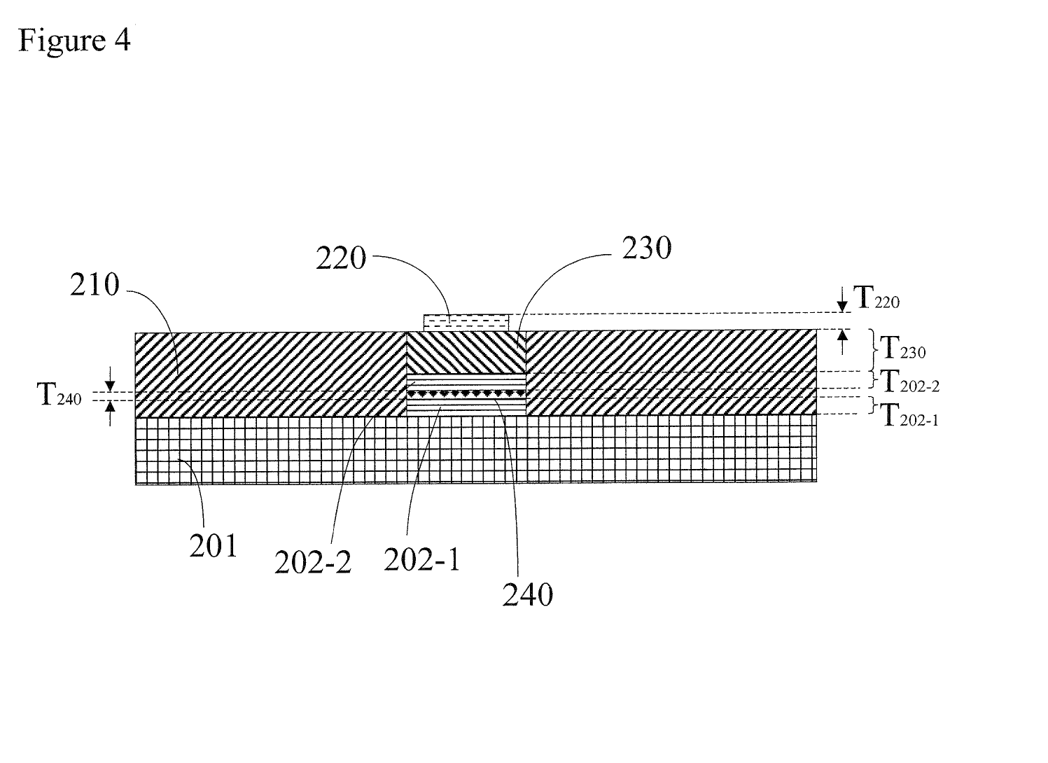

FIG. 4 illustrates a cross-sectional schematic of an embodiment of the invention. Buffer layer 202-1 can overlie substrate 201. Superconductor 210-1 can overlie buffer layer 202-1. A second buffer layer 202-2 can overlie superconductor 210-1. A second superconductor 210-2 can overlie buffer 202-2. With the above-described masking procedure a ferroelectric 230 can be formed within superconductor 210-2. Finally electrode 220 can be formed overlying ferroelectric 230. The thicknesses T₂₀₂₋₁ and T₂₀₂₋₂ of buffer layers 202-1 and 202-2 can be about 2 nm to about 50 nm, preferably about 7.2 nm, the thickness T₂₄₀ of superconductor 210-1 can be about 1 nm to about 20 nm, preferably about 2.4 nm, and the thickness T₂₃₀ of ferroelectric 230 can be about 50 nm to about 2000 nm, preferably about 300 nm.

In various embodiments of the invention superconductor 210 can be YBa₂Cu₃O₇₋ₓ (YBCO), or GdBa₂Cu₃O₇₋ₓ (GBCO), where in both cases x can be between 0 and 0.4. Superconductor 210 can be any superconducting material having a pairing symmetry corresponding to a zero or a non-zero angular momentum. Buffer layers 202-1 and 202-2 can be, for example, PrBa₂Cu₃O₇ (PrBCO), which is a semi-conductor with a lattice structure closely matching the lattice structure of YBCO and GBCO. Ferroelectric 230 can be, for example, Pb(ZrₓTi₁₋ₓ)O₃(PZT). Substrate 201 can be, for example, SrTiO₃, or sapphire, which has a higher relaxation rate than SrTiO₃.

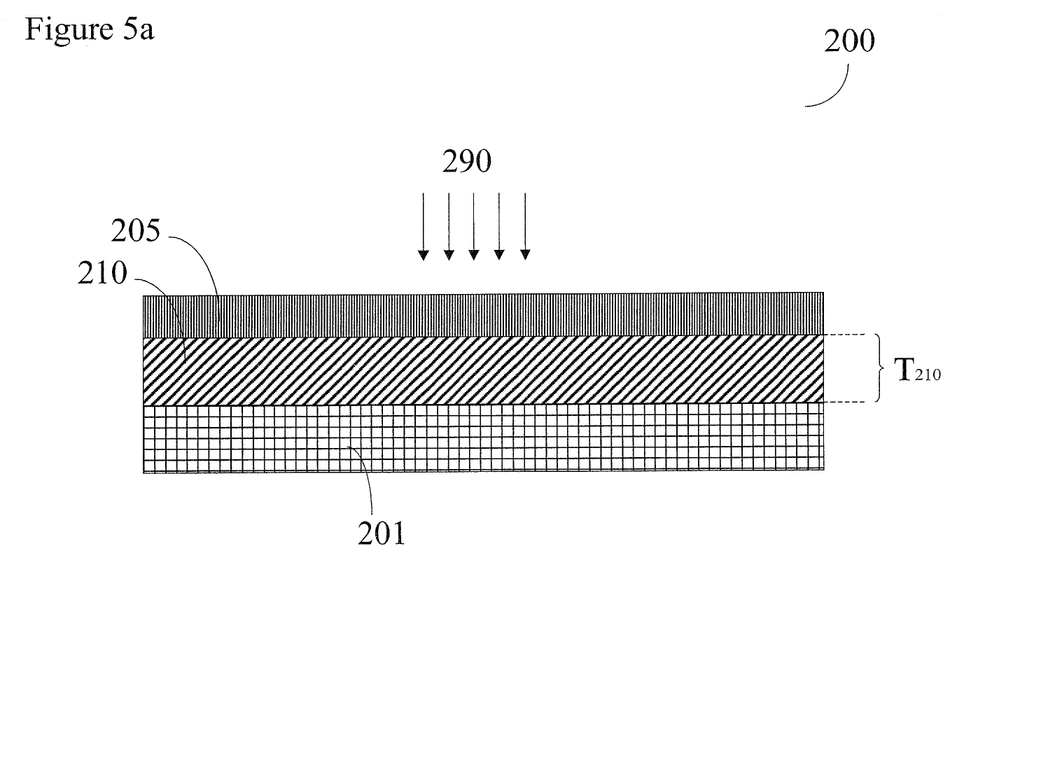

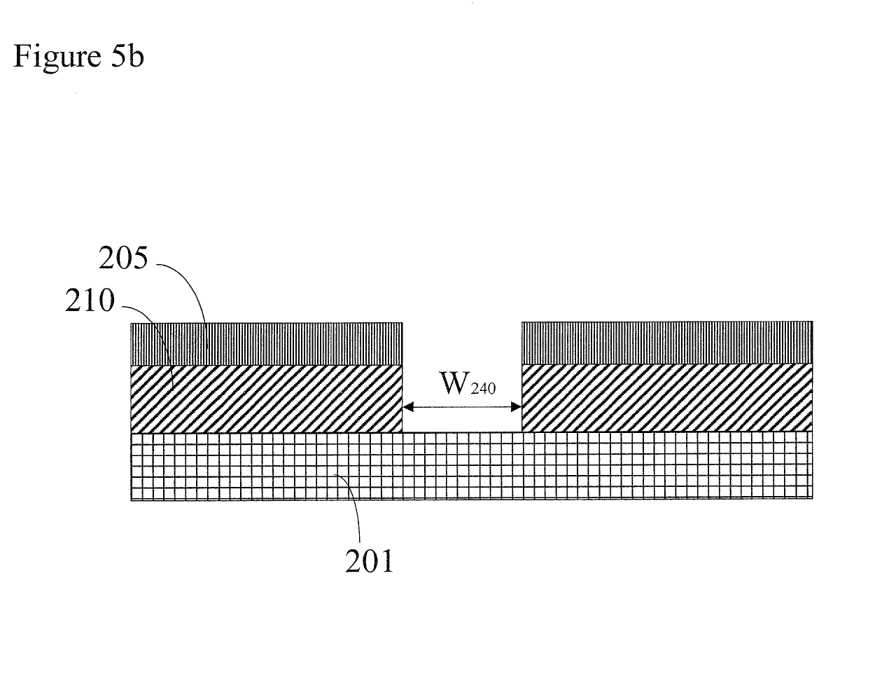

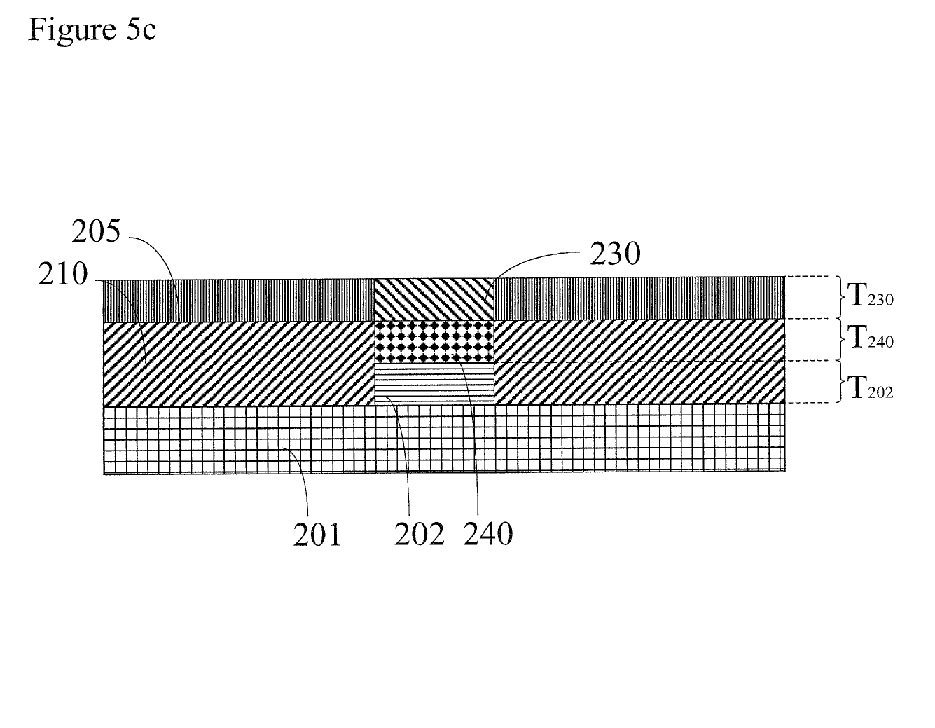

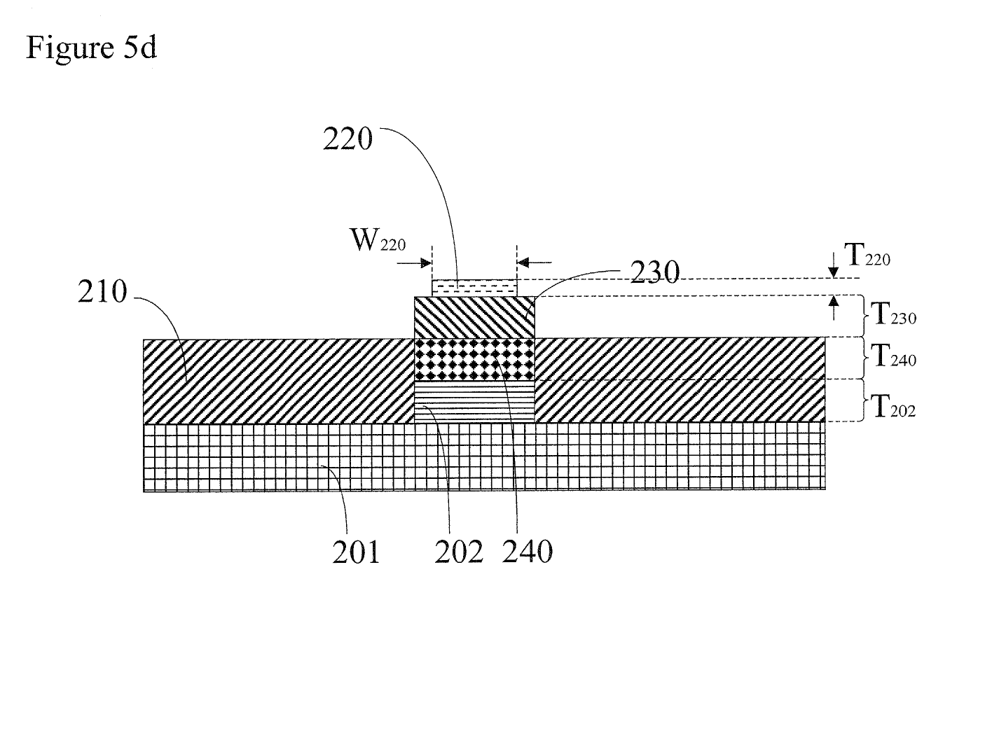

FIGS. 5a through 5d illustrate another embodiment of the invention. FIG. 5a illustrates a cross-sectional view of substrate 201, superconductor 210 of thickness T₂₁₀, overlying substrate 201, and mask 205, overlying superconductor 210. FIG. 5b shows that using well-known techniques of lithography, for example electron beam lithography, masked region of width W₂₄₀ can be removed from superconductor 210. FIG. 5c illustrates the addition of buffer layer 202, superconducting layer 240, and ferroelectric 230, with thicknesses of T₂₀₂, T₂₄₀, and T₂₃₀, respectively. In FIG. 5d electrode 220 has been deposited with thickness T₂₂₀, while mask 205 has been removed. In a further embodiment of the invention, a second buffer layer can be added between supreconducting layer 240 and ferroelectric 230.

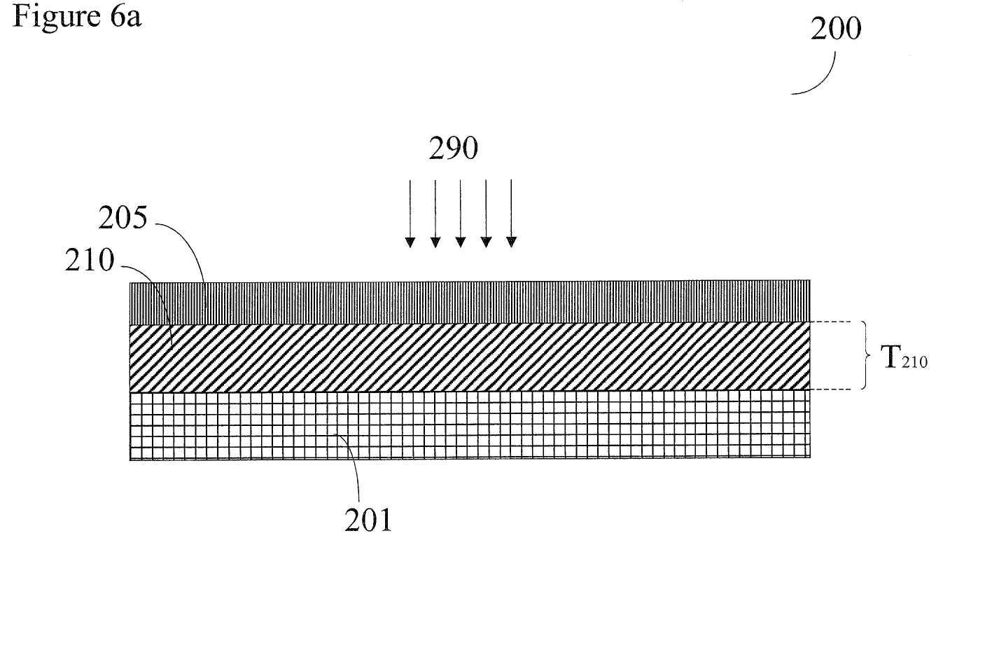

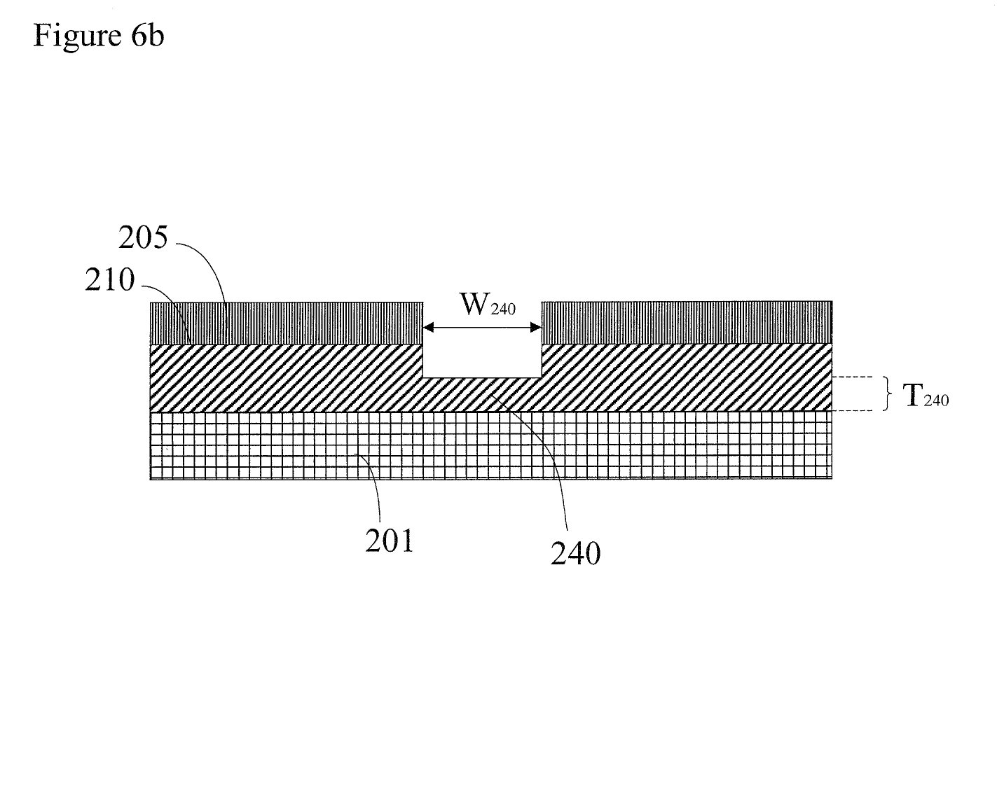

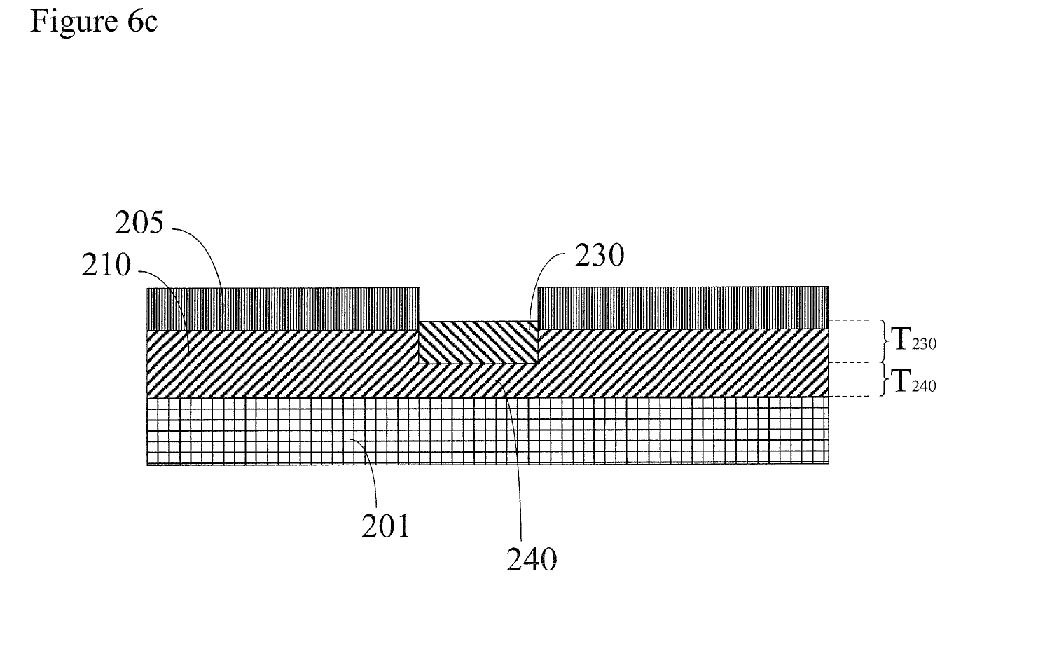

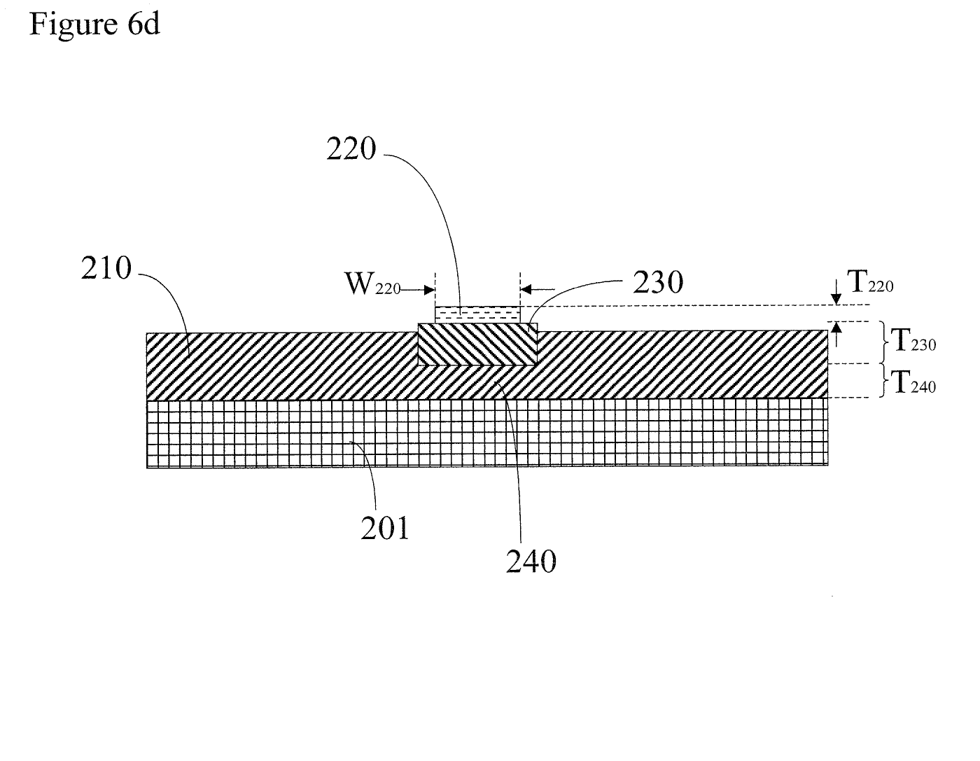

FIGS. 6a through 6d illustrate additional embodiments of the invention, where superconductor 210 is doped near the superconductor-insulator transition point, but the thickness of the superconductor 210 is greater than is required for the ferroelectric field effect to work. FIG. 6a illustrates a cross-sectional view of substrate 201, superconductor 210 of thickness T₂₁₀, overlying substrate 201, and mask 205, overlying superconductor 210. Lithographic techniques can be used to remove masked region 290 of mask 205 and superconductor 210 of width W₂₄₀, so that superconducting layer 240 remains with thickness T₂₄₀, as illustrated in FIG. 6b. FIG. 6c illustrates ferroelectric 230, of thickness T₂₃₀, overlying superconducting layer 240. FIG. 6d illustrates electrode 220, of thickness T₂₂₀ and width W₂₂₀, overlying ferroelectric 230. Buffer layer 202 can be deposited between superconductor 240 and ferroelectric 230.

The quantum mechanical evolution of the qubits of a quantum computer can be secured by completely decoupling them from the surrounding system and environment. However, in order to apply quantum algorithms, certain operations are performed, including entangling the quantum states of the qubits at some points, applying quantum gates at other points, and reading and initializing the state of the qubit. Each of these operations require coupling the qubit to some aspect of the surrounding system. For example, in order to read the state of a qubit with a SQUID architecture, the supercurrents of the SQUID have to be directly manipulated. Also, entangling the quantum states of two qubits requires establishing a direct contact between the qubits, for example by establishing a coherent superconducting switch between them. One requisite of a coherent switch 200 is that the phases of the supercurrents remain unperturbed during the transitions of the switch.

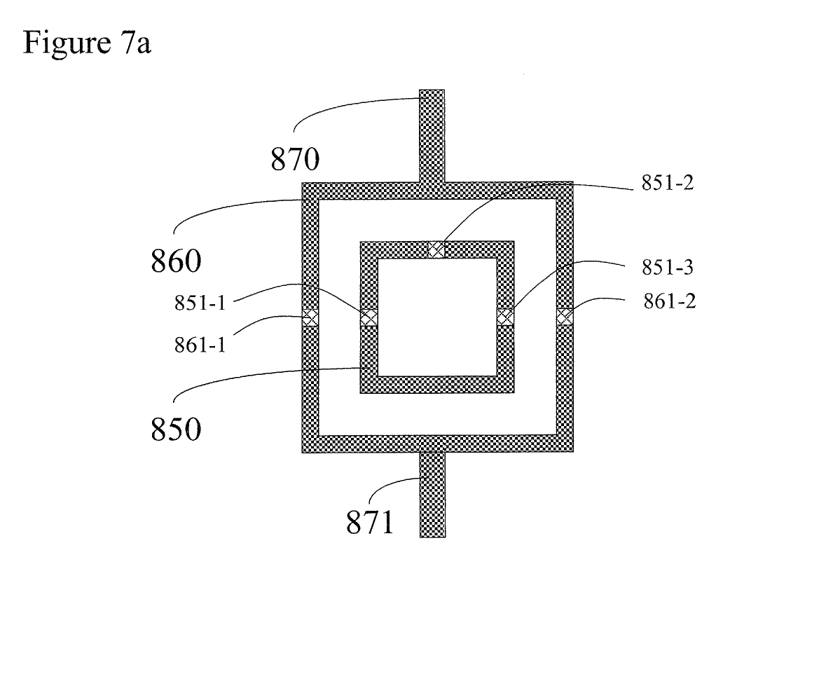

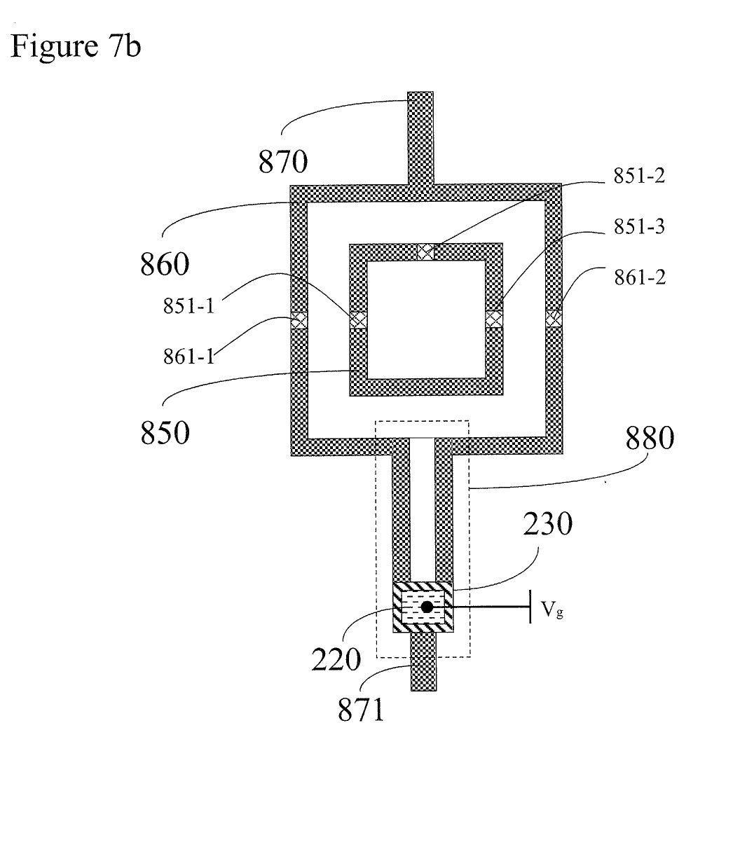

FIG. 7a illustrates another solid state realization of a qubit, as first proposed in Caspar H. van der Wal, A. C. J. ter Haar, F. K. Wilhelm, R. N. Schouten, C. J. P. M. Harmans, T. P. Orlando, Seth Loyd, and J. E. Mooij, “Quantum Superposition of Macroscopic Persistent-Current States,” Science 290, 773 (Oct. 27, 2000), which is incorporated herein by reference in its entirety. The qubit is the inner superconducting loop, 850, which can include three or four Josephson junctions 850-1 through 850-3. In order to interact with the qubit, dc-SQUID 860 can be fabricated to surround loop 850. Dc-SQUID 860 also can contain Josephson junctions 861-1, 861-2, and can be coupled to the rest of the circuitry through leads 870 and 871. Since the supercurrents of the quantum states of loop 850 are directly related to the supercurrents of dc-SQUID 860 through a coupling of their magnetic fluxes, the quantum state of the qubit can be read by sensing the supercurrents of dc-SQUID 860. However, when loop 850 performs quantum computations, it is decoupled from dc-SQUID 860. In the experiment by van der Wal et al., the surrounding DC-SQUID 860 could not be decoupled from the inner superconducting loop 850, a problem described in the reference as limiting the coherence of the system. Thus, quantum computation is limited in such a system.

An embodiment of the invention could provide a mechanism for decoupling dc-SQUID 860 reversibly from superconducting loop 850 by including coherent switch 200 into dc-SQUID 860. When coherent switch 200 is closed, the supercurrent of superconducting loop 850 is inductively coupled to the dc-SQUID 860, thus causing the flow of supercurrent in dc-SQUID 860. By sensing the supercurrent of dc-SQUID 860 the quantum state of the qubit can be read out. When the switch is open, no supercurrent can flow in dc-SQUID 860, thus loop 850 is well isolated and can perform quantum computations undisturbed by dc-SQUID 860.

FIG. 7b shows an embodiment of a coherent switch. In order to minimize coupling between coherent switch 200 and loop 850, a portion of dc-SQUID 860 can form elongated branch 880. When a sufficient voltage V_{g} is applied to electrode 220, ferroelectric material 230 polarizes and changes the underlying region of dc-SQUID 860 from superconducting to insulating. This insulating region prevents the flow of a supercurrent in dc-SQUID 860, thus decoupling dc-SQUID 860 from loop 850. When the voltage is removed, ferroelectric 230 relaxes, allowing the underlying region of dc-SQUID 860 to change from insulating back to superconducting. This change allows the flow of supercurrents in dc-SQUID 860 again, thus allowing the reading of the quantum states of loop 850 by dc-SQUID 860.

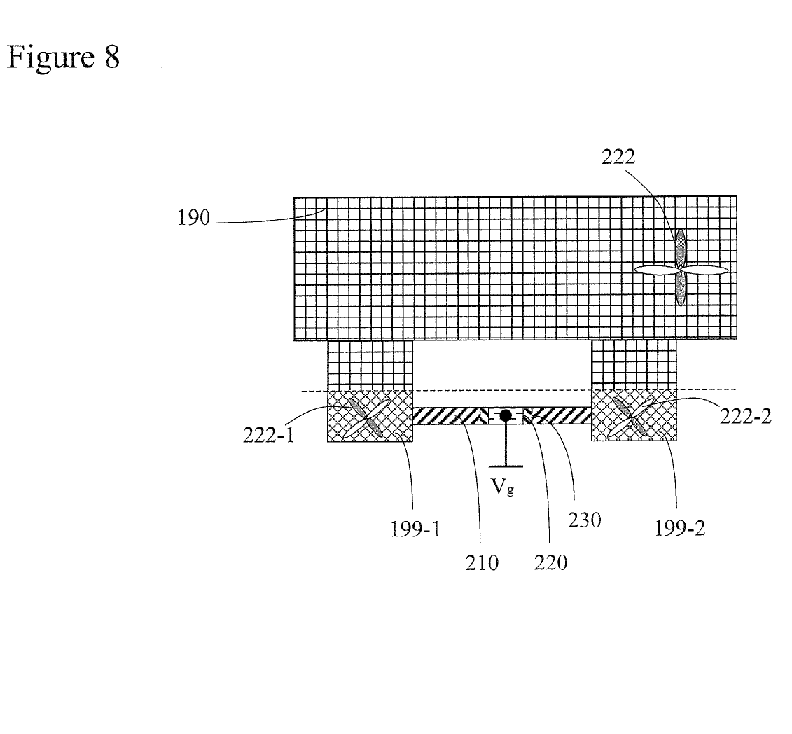

FIG. 8 illustrates another embodiment of the invention, where a qubit system is formed with superconductors, having a pairing symmetry corresponding to a non-zero angular momentum. This qubit system was first disclosed by Alexandre Zagoskin, U.S. patent application Ser. No. 09/452,749, “Permanent Readout Superconducting Qubit”, filed Dec. 1, 1999, incorporated herein by reference in its entirety. The orientation of the main axes of the lattice of superconductor 190 is shown by the square hatching. The orientation of the pairing symmetry is shown by d-wave order parameter 222. Crystal field effects typically align the orientation of the pairing symmetry with the main lattice axes. Qubits 199-1 and 199-2 have their lattice axes and correspondingly their pairing symmetry orientation rotated by 45 degree relative to that of superconductor 190, as shown by d-wave order parameters 222-1 and 222-2. The orientation of the order parameters 222-1 and 222-2 of the qubits can have any angle relative to order parameter 222. Superconductor 190 can be coupled to qubits 199-1 and 199-2, respectively, by tunnel junctions, proximity junctions, or any other well known ways of forming a weak link between superconductors, as indicated by the dotted line. The quantum states of qubits 199-1 and 199-2 can be the different amount of flux, which can be trapped at the boundary between qubits 199-1 and 199-2 and superconductor 190.

Qubits 199-1 and 199-2 can be coupled to each other through a superconducting bridge 890, interrupted by coherent switch 200. Similarly to the previous embodiments, electrode 220 can overlie ferroelectric 230, which can either overlie, or be embedded or be partially embedded into superconductor 210. In analogy to previous embodiments, coherent switch 200 can be opened by applying a sufficient voltage V_{g} to electrode 220. The electric field of the polarized ferroelectric 230 can change superconductor 210 from superconducting to insulating, thus preventing the flow of a supercurrent, and decoupling qubits 199-1 and 199-2. Coherent switch 200 can be closed by not applying a sufficient voltage to electrode 220, either by completely removing voltage V_{g}, or by applying a voltage too small to polarize ferroelectric 230. Then ferroelectric 230 will relax, allowing superconductor 210 to change back from insulating to superconducting. Once superconductor 210 is superconducting again, the connection between qubits 199-1 and 199-2 is restored. Superconductor 210 can have a thickness of about 1 nm to about 20 nm, preferably about 2.4 nm. Superconductor 210 can be covered by a buffer layer as well.

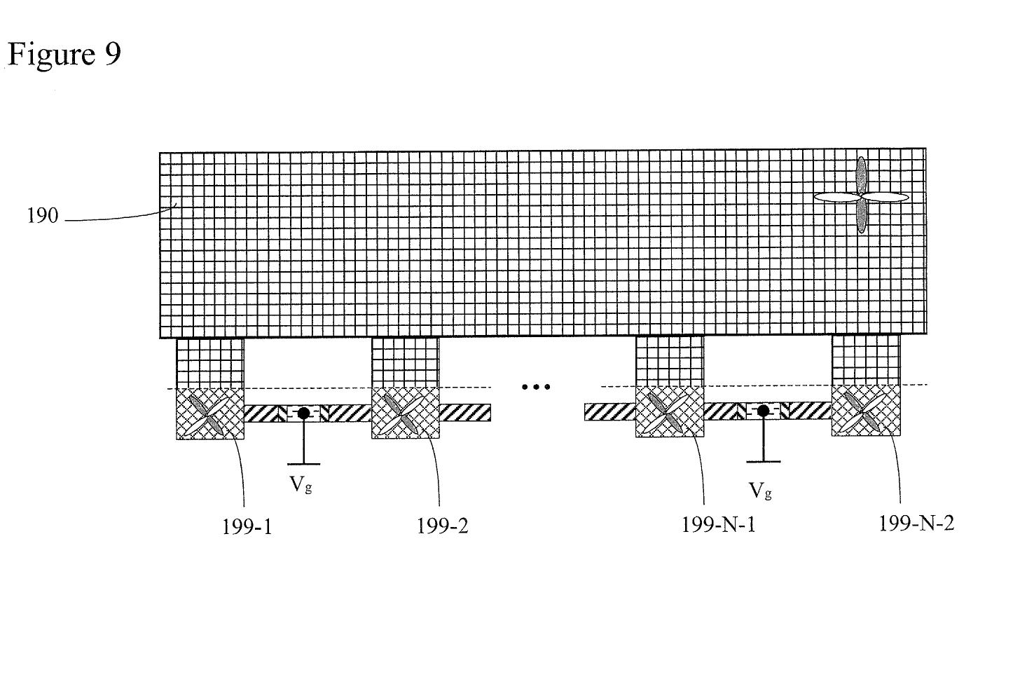

FIG. 9 illustrates another embodiment of the invention, where coherent switches 200-1 through 200-N couple qubit 199-1-1 to qubit 199-1-2 through qubit 199-N-1 to qubit 199-N-2. The operation of individual coherent switches 200-1 through 200-N is analogous to the previously described embodiments. This embodiment is capable of manipulating selected qubits within a system of qubits, a necessary step towards applying the present invention in quantum computer systems.

Although the invention has been described with reference to particular embodiments, the described embodiments were meant only to serve as examples. Various adaptations and combinations of the features of the disclosed embodiments are intended to be within the scope of the invention, as defined by the following claims.

1. A method of switching of a superconducting computer element, comprising
coupling the superconducting computer element to a ferroelectric; and
causing a portion of the superconducting computer element to transition between a superconducting and an insulating state by changing the polarization of the ferroelectric.

2. The method of claim 1, wherein the coupling of the superconducting computer element to the ferroelectric comprises
forming at least one superconductor layer as a part of the superconducting computer element; and
forming the ferroelectric at least partially overlying the superconductor layer.

3. The method of claim 2, wherein the coupling of the superconducting computer element to the ferroelectric comprises
forming a plurality of ferroelectric regions, individually overlying the superconductor layer at least partially.

4. The method of claim 2, wherein the forming the superconductor layer comprises
forming a first buffer layer over a substrate;
forming the superconductor layer over the first buffer layer; and
forming a second buffer layer over at least portions of the superconductor layer.

5. The method of claim 2, wherein the coupling of the superconducting computer element to the ferroelectric comprises
forming a thin portion of the superconductor layer, with thickness smaller than the surrounding areas of the superconductor layer; and
forming the ferroelectric, at least partially overlying the thin portion of the superconductor layer.

6. The method of claim 2, wherein the forming the superconductor layer comprises
using lithographic techniques to form the thin portion of the superconductor layer.

7. The method of claim 2, wherein the coupling of the superconducting computer element to the ferroelectric comprises
forming the superconductor layer with a thickness such that the ferroelectric is capable of causing a transition of the superconductor layer between a superconducting and an insulating state.

8. The method of claim 2, wherein the coupling of the superconducting computer element to the ferroelectric comprises
forming the ferroelectric at a distance from the superconducting layer such that the ferroelectric is capable of causing a transition of the superconductor layer between a superconducting and an insulating state.

9. The method of claim 1, wherein the causing the transition of a portion of the superconducting computer element comprises
generating an electric field by the ferroelectric, capable of causing the transition of a portion of the superconducting computer element to transition between a superconducting and an insulating state.

10. The method of claim 9, wherein the generating of the electric field comprises
applying a voltage to the ferroelectric.

11. The method of claim 1, wherein the coupling of the superconducting computer element to the ferroelectric comprises
forming a quantum bit as the superconducting computer element;
forming a sensor coupled to the quantum bit; and
coupling the ferroelectric to the sensor.

12. The method of claim 11, wherein the coupling the ferroelectric to the sensor comprises
having supercurrents in the sensor; and
modifying the supercurrents by causing a portion of the sensor to transition between a superconducting and an insulating state.

13. The method of claim 12, wherein the generating of the supercurrents in the sensor comprises
generating supercurrents in the quantum bit;
inducing supercurrents in the sensor by an inductive coupling between the quantum bit and the sensor.

14. The method of claim 12, wherein the modifying the supercurrents comprises
suppressing the supercurrents by causing at least portions of the sensor to transition into an insulating state.

15. The method of claim 11, wherein the forming of the quantum bit comprises
forming a superconductor layer with a pairing symmetry corresponding to non-zero angular momentum.

16. The method of claim 1, wherein the coupling of the superconducting computer element to the ferroelectric comprises
forming a pair of permanent readout superconducting qubits as the superconducting computer element;
forming a superconducting bridge coupling the permanent readout superconducting qubits; and
coupling the ferroelectric to the superconducting bridge.

17. The method of claim 16, further comprising
entangling the quantum states of the pair of permanent readout superconducting qubits by causing the superconducting bridge coupling the pair to transition into a superconducting state.

18. The method of claim 1, wherein the coupling of the superconducting computer element to the ferroelectric comprises
forming a plurality of pairs of permanent readout superconducting qubits as the superconducting computer element;
forming a plurality of superconducting bridges coupling the permanent readout superconducting qubits pair wise individually; and
coupling a plurality of ferroelectrics to the plurality of superconducting bridges individually.

19. The method of claim 18, further comprising
entangling the quantum states of the pair of permanent readout superconducting qubits individually by causing the corresponding superconducting bridges coupling the individual pair to transition into a superconducting state.

20. A switch, comprising
a superconducting computer element; and
a ferroelectric, coupled to the superconducting computer element.

21. The switch of claim 20, wherein the superconducting computer element comprises
a superconducting layer, overlying a substrate.

22. The switch of claim 21, wherein the superconducting layer comprises a thin portion.

23. The switch of claim 21, wherein the ferroelectric overlies at least portions of the superconducting layer

24. The switch of claim 21, wherein the ferroelectric comprises a plurality of ferroelectric regions, individually overlying at least portions of the superconductor layer.

25. The switch of claim 21, wherein
the thickness of the superconductor layer is between about 1 nm and about 20 nm; and
the thickness of the ferroelectric is between about 50 nm and about 10,000 nm.

26. The switch of claim 21, further comprising
at least one buffer layer above or below the superconducting layer; having a thickness between about 2 nm and about 100 nm.

27. The switch of claim 21, wherein
the superconductor is a high temperature superconductor with a doping sufficiently close to the critical doping, such that the ferroelectric is capable of causing the superconductor to transition between a superconducting and an insulating state.

28. The switch of claim 21, wherein
the superconductor has a pairing symmetry corresponding to a non-zero angular momentum.

29. The switch of claim 1, wherein
the ferroelectric comprises Pb(ZrₓTi₁₋ₓ) O₃.

30. The switch of claim 20, comprising
an electrode, overlying the ferroelectric.

31. The switch of claim 20, wherein the superconducting computer element comprises
a quantum bit;
a sensor, coupled to the quantum bit.

32. The switch of claim 31, wherein the sensor comprises
a superconducting loop, comprising one or more Josephson junctions, inductively coupled to the quantum bit.

33. The switch of claim 31, wherein the sensor comprises
a superconducting loop, comprising three or four Josephson junctions, inductively coupled to the quantum bit.

34. The switch of claim 31, wherein
the ferroelectric is formed overlying the sensor such that it is capable of causing a portion of the sensor to transition between a superconducting and an insulating state.

35. The switch of claim 31, wherein
the material of the quantum bit is a superconductor with a pairing symmetry corresponding to a non-zero angular momentum.

36. The switch of claim 35, wherein the superconductor material is a d-wave superconductor.

37. The switch of claim 36, wherein the d-wave superconductor material is YBa₂Cu₃O₇₋ₓ, wherein x is between 0 and about 0.6.

38. The switch of claim 36, wherein the d-wave superconductor material is GdBa₂Cu₃O₇₋ₓ, where x is between 0 and about 0.6.

39. The switch of claim 35, wherein the superconductor material is a p-wave superconductor.

40. The switch of claim 20, wherein the superconducting computer element comprises
a pair of permanent readout superconducting quantum bits.

41. The switch of claim 40, wherein
the pair of the permanent readout superconducting quantum bits are coupled by a superconducting bridge; and
the ferroelectric is coupled to the superconducting bridge.

42. The switch of claim 41, wherein
the ferroelectric is formed overlying the superconducting bridge such that it is capable of causing portions of the superconducting bridge to transition between a superconducting state and an insulating state.
